(19) United States
(12) Patent Application Publication
(10) Pub. No.: US 2024/0071948 A1
(43) Pub. Date: Feb. 29, 2024

(54) SEMICONDUCTOR PACKAGE WITH STIFFENER BASKET PORTION

(71) Applicant: Intel Corporation, Santa Clara, CA (US)

(72) Inventors: Jiun Hann SIR, Pulau Pinang (MY); Eng Huat GOH, Ayer Itam (MY); Poh Boon KHOO, Pulau Pinang (MY); Nurul Khalidah YUSOP, Perak (MY); Saw Beng TEOH, Folsom, CA (US); Chan Kim LEE, Penang (MY)

(21) Appl. No.: 17/895,112

(22) Filed: Aug. 25, 2022

(51) Int. Cl. H01L 23/00; H01L 23/16; H01L 23/367; H01L 25/00; H01L 25/065

(52) U.S. Cl. CPC H01L 23/562; H01L 23/16; H01L 23/367; H01L 25/0657; H01L 25/50; H01L 2225/06506; H01L 2225/0651; H01L 2225/06562; H01L 2225/06586; H01L 2225/06589

(57) ABSTRACT

A semiconductor package is provided including: a package substrate with a top surface, wherein the top surface extends to a peripheral side surface of the package substrate; a stiffener with a lateral portion and a basket portion, wherein the lateral portion is positioned over the top surface of the package substrate and the basket portion overhangs from the top surface of the package substrate adjacent to the peripheral side surface of the package substrate; at least one semiconductor die positioned in the basket portion of the stiffener; and at least one wire attached to the at least one semiconductor die and extending out of the basket portion of the stiffener.

### BACKGROUND

In semiconductor manufacturing, there may be challenges in device form-factor, e.g., package real-estate expansion due to on-package dynamic random access memory (DRAM) devices scaling for improved computing performance. For example, a memory-on-package architecture with semiconductor dies (e.g., DRAM devices) mounted on top of a package substrate next to other electrical components (e.g., a central processing unit (CPU), or a graphic processing unit (GPU), which are also disposed on the package substrate, may lead to an increase in total package height due to the height of the DRAM devices. Further, since the DRAM devices, which are mounted on the package substrate, are often higher than the other electrical components, thermal management may be more difficult due to the size differences between the DRAM devices and the electrical components.

Moreover, in conventional semiconductor manufacturing, there may be challenges associated with signal transmission induced by the wires of the DRAM devices being connected to a memory substrate.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the present disclosure. The dimensions of the various features or elements may be arbitrarily expanded or reduced for clarity. In the following description, various aspects of the present disclosure are described with reference to the following drawings, in which:

FIG. 1A illustrates a cross-sectional view of a conventional semiconductor package;

FIG. 1B illustrates a cross-sectional view of a conventional semiconductor package;

FIG. 2A illustrates a cross-sectional view of a semiconductor package in accordance with an aspect of the disclosure;

FIG. 2B illustrates a top view of the semiconductor package of FIG. 2A in accordance with an aspect of the disclosure;

FIG. 2C illustrates a cross-sectional view of a semiconductor package in accordance with an aspect of the disclosure;

FIG. 2D illustrates a top view of the semiconductor package of FIG. 2C in accordance with an aspect of the disclosure;

FIG. 3A illustrates a cross-sectional view of a stiffener on a package substrate in accordance with an aspect of the disclosure;

FIG. 3B illustrates a top view of the stiffener on the package substrate of FIG. 3A in accordance with an aspect of the disclosure;

FIG. 4A illustrates a cross-sectional view of a semiconductor package in accordance with an aspect of the disclosure;

FIG. 4B illustrates a simplified topology view of the semiconductor package of FIG. 4A in accordance with an aspect of the disclosure;

FIG. 5 illustrates a simplified topology view of the semiconductor package of FIGS. 2A, 2B, 2C and 2D in accordance with an aspect of the disclosure;

FIG. 6 shows a simplified flow diagram for an exemplary method for making semiconductor packages according to an aspect of the present disclosure;

FIG. 7A to FIG. 7L illustrate a process for making the semiconductor package in accordance with an aspect of the disclosure; and

FIG. 8 shows an illustration of a computing device that includes a present semiconductor package according to a further aspect of the present disclosure.

### DETAILED DESCRIPTION

The following detailed description refers to the accompanying drawings that show, by way of illustration, specific details, and aspects in which the present disclosure may be practiced. These aspects are described in sufficient detail to enable those skilled in the art to practice the present disclosure. Various aspects are provided for devices, and various aspects are provided for methods. It will be understood that the basic properties of the devices also hold for the methods and vice versa. Other aspects may be utilized and structural, and logical changes may be made without departing from the scope of the present disclosure. The various aspects are not necessarily mutually exclusive, as some aspects can be combined with one or more other aspects to form new aspects.

Combining multiple integrated circuit dies in a single semiconductor package without stacking them into a three-dimensional integrated circuit (3D-IC) with through-silicon vias (TSVs) is commonly referred to as a 2.5D stacked integrated circuit (2.5D IC). In this kind of semiconductor package, many of the advantages of 3D integration can be approximated by placing electrical components (e.g., CPU and/or GPU) and semiconductor dies (e.g., DRAM devices) side by side on the package substrate instead of stacking them vertically. If the pitch is very fine, the assembly can be packaged as a single component with better size, weight, and power characteristics than a comparable 2D package or circuit board assembly. Problems encountered in such semiconductor packages, particularly where the electrical components do not have the same height, is an increase in package height due to the often taller DRAM devices, an increase in the size of the package substrate due to the additional space consumed by the DRAM devices and a more complicated thermal solution due to the different surface height between the electrical components and the DRAM devices. Moreover, the wire connection between the electrical components and the DRAM devices is often complicated which may result in transmission loss.

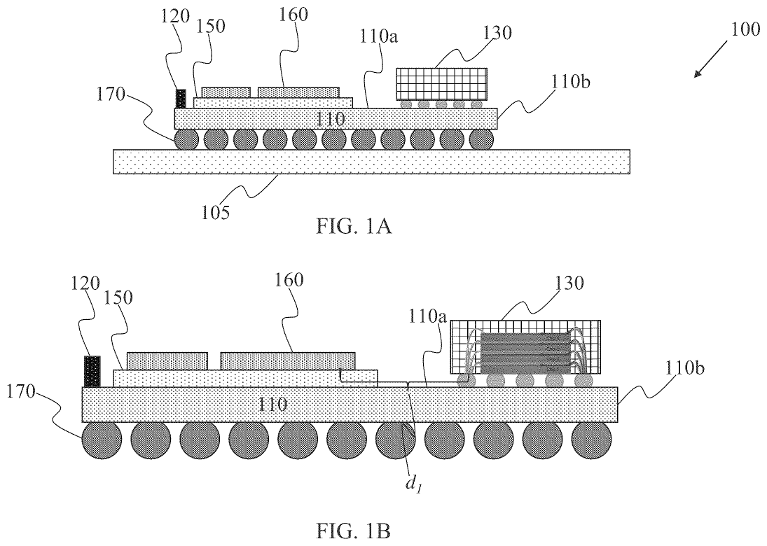

FIG. 1A and FIG. 1B illustrate such a conventional semiconductor package 100. In FIG. 1A, a package substrate 110 may include a base die 150 disposed on a top surface 110a of the package substrate 110, in which the top surface 110a extends to a peripheral side surface 110b of the package substrate 110. The base die 150 may include an electrical component 160 disposed on a top surface of the base die 150. A stiffener 120 is disposed adjacent to the base die 150. Solder balls 170 may be interposed between a bottom surface of the package substrate 110 and a motherboard 105. A memory package 130 may be positioned adjacent to the base die 150 and the electrical component 160 on a top surface 110a of the package substrate 110. FIG. 1B illustrates at least one wire attached to the at least one semiconductor die 130 and connecting to a memory substrate. The connection between the at least one semiconductor die 130 and the electrical component 160 is indicated in FIG. 1B as a distance ob.

A disadvantage associated with this conventional semiconductor package 100 may include problems with the differing height between the at least one semiconductor die 130 and the electrical component 160, causing the problems stated above. For example, not only may the difference in height cause an increase in the overall height of the semiconductor package 100, thereby inhibiting miniaturization, the difference in height may also create a problem in temperature control, since it may hinder the placement of additional components (e.g., a fan, or a heat spreader, not shown). A further problem may arise from the electrical connection between the at least one semiconductor die 130 and the electrical component 160, which involves routing from the semiconductor die 130 via the package substrate 110 to the electrical component 160, which may be associated with transmission loss.

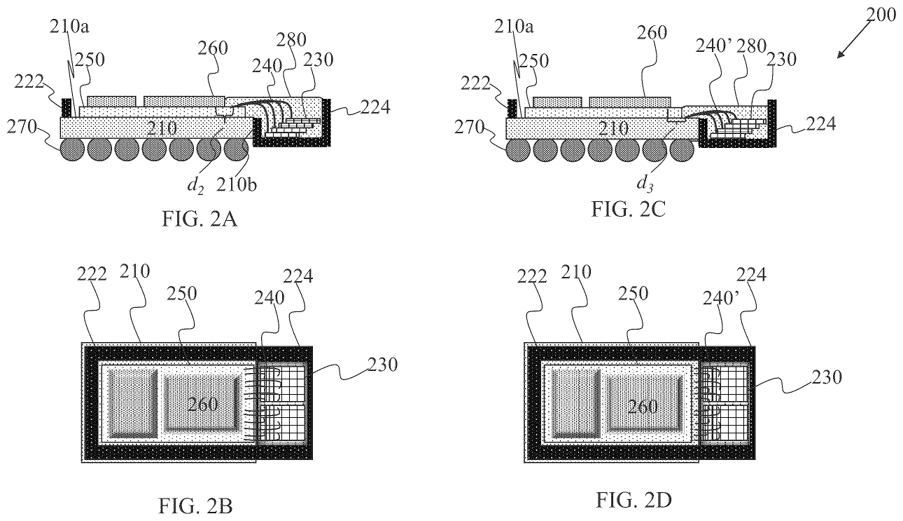

According to the present disclosure, as illustrated in FIG. 2A, FIG. 2B, FIG. 2C and FIG. 2D, there is provided a semiconductor package 200 including a package substrate 210 with a top surface 210a, in which the top surface 210a extends to a peripheral side surface 210b of the package substrate 210. The semiconductor package 200 may include a stiffener 220 with a lateral portion 222 and a basket portion 224, in which the lateral portion 222 is positioned over the top surface 210a of the package substrate 210 and the basket portion 224 may overhang from the top surface 210a of the package substrate 210 adjacent to the peripheral side surface 210b of the package substrate 210. The semiconductor package 200 may include at least one semiconductor die 230 positioned in the basket portion 224 of the stiffener 220. The semiconductor package 200 may include at least one wire 230 attached to the at least one semiconductor die 230 and extending out of the basket portion 224 of the stiffener 220. In an aspect, the at least one semiconductor die 230 may be a stack of semiconductor dies.

Advantageously, since the stiffener 220 has the basket portion 224 overhanging from the top surface 210a of the package substrate 210 adjacent to the peripheral side surface 210b of the package substrate 210, it is possible to place at least one semiconductor die 230 into the basket portion 224, thereby placing the at least one semiconductor die 230 substantially adjacent to the package substrate 210, instead of on a top surface 210a of the package substrate 210. This placement of the at least one semiconductor die 230 may ameliorate the problems associated with the height difference. For example, advantageously, the vertical package size may be reduced by the placement of the at least one semiconductor die 230 in the the basket portion 224, since the at least one semiconductor die 230 may be placed at a horizontal level below the top surface 210a of the package substrate 210. Furthermore, since the height differences between the electrical component 260 and the at least one semiconductor die 230 may be reduced or possibly at the same or similar levels, the placement of additional components (e.g., a fan, or a heat spreader, not shown) on the semiconductor package 200 for heat removal may be facilitated, thereby providing an improvement in temperature control.

The package substrate 210 may include typical substrate materials. For example, the package substrate 210 may include an epoxy-based laminate substrate having a core layer for mechanical support and/or build-up layers. In one aspect, the package substrate 210 may include a coreless substrate i.e., an epoxy-based laminate substrate, and/or build-up layers without a rigid core layer. The package substrate 210 may include other suitable types of substrates in other aspects. For example, the package substrate 210 may include any suitable semiconductor material (e.g., silicon, gallium, indium, germanium, or variations or combinations thereof, among other substrates), one or more insulating layers, such as glass-reinforced epoxy, such as FR-4, polytetrafluoroethylene, cotton-paper reinforced epoxy, phenolic-glass, paper-phenolic, polyester-glass, ajinomoto build-up film, any other dielectric material, such as bismaleimide-triazine epoxy resin, or any combination thereof, such as can be used in electronic package substrate and/or printed circuit boards (PCBs).

The at least one semiconductor die 230 may include a plurality of semiconductor dies, each of which may include, e.g., a memory device (e.g., SRAM, DRAM, flash memory, EEPROM, etc.), a radio frequency integrated circuit (RFIC), a deep learning processor (DLP) or a neural network processor. The at least one semiconductor die 230 may be partially or entirely disposed in the basket portion 224.

Each of the at least one semiconductor dies 230 may have at least one wire 240 attached to it. The at least one wire 240 may be configured to extend out of the basket portion of the stiffener 224.

The semiconductor package 200 may further include a base die 250 disposed on the top surface 210a of the package substrate 210. The base die 250 may include a silicon interposer or a stack-up of metal redistribution layers (not shown).

As illustrated in FIG. 2A, the at least one wire 240 may connect the at least one semiconductor die 230 with the base die 250. Advantageously, such an electrical connection between the at least one semiconductor die 230 and the base die 250 may reduce the distance for transmission. In other words, the distance indicated as d₂ in FIG. 2A may be shorter than the distance indicated as d₁ in FIG. 1B. Such a reduced distance may have benefits such as an improved bandwidth and a lower power consumption, which may result in an improved performance of the semiconductor package 200.

As illustrated in FIG. 2C, the at least one wire 240′ may alternatively connect the at least one semiconductor die 230 with the package substrate 210. Advantageously, such an electrical connection between the at least one semiconductor die 230 and the package substrate 210 may also reduce the distance for transmission between them. In other words, the distance indicated as d₃ in FIG. 2C may be shorter than the distance indicated as d₁ in FIG. 1B. Such a reduced distance may have benefits such as an improved bandwidth and a lower power consumption, which may result in an improved performance of the semiconductor package 200.

The base die 250 may have a top surface and at least one electrical component 260 may be disposed on the top surface of the base die 250. The electronic component 260 may be any electronic device or component, which may be included in the semiconductor package 200, such as a semiconductor device (e.g., a die, a chip, a processor, computer memory, a platform controller hub, etc.). In one aspect, one of the electronic components 260 may represent a discrete chip. The electronic component 260 may include, or be a part of a processor (e.g., a CPU, a GPU, etc.), a memory device (e.g., SRAM, DRAM, flash memory, EEPROM, etc.), an application specific integrated circuit, a platform controller hub, a field programmable gate array, a system on a chip, a 3D-IC stack, a neural network accelerator, a system in a package, or a package on a package in some aspects. Although two electronic components are depicted in the Figures, any suitable number of electronic components 260 may be included.

The package substrate 210 may include electrically conductive elements or electrical routing features (not shown) configured to route electrical signals to or from the base die 250. The electrical routing features may be internal (e.g., disposed at least partially within a thickness of the package substrate 210) and/or external to the package substrate 210. For example, in some aspects, the package substrate 210 may include electrical routing features such as pads, vias, and/or traces configured to receive the interconnect structures and route electrical signals to or from the base die 250.

The semiconductor package 200 may also include interconnects, such as solder balls 270, for coupling with a motherboard (not shown) for connection to a power supply, ground termination and/or signaling. The solder balls 270 may be attached to a bottom surface of the package substrate 210 and optionally, a section of the basket portion 224 extending below the bottom surface of the package substrate 210. In some aspects, the solder balls 270 that are attached to the bottom surface may have a diameter that is greater than a height of the section of the basket portion 224 below the bottom surface of the package substrate 210.

The stiffener 220 can be affixed (i.e., mechanically coupled or otherwise attached) to the package substrate 210 in any suitable manner. The stiffener 220 may have a lateral portion 222 and a basket portion 224.

The lateral portion 222 and/or the basket portion 224 may extend to the same height as the plurality of electrical components 260. Hence, the lateral portion 222 and/or the basket portion 224 may together with a top surface of the electrical components 260 form a surface that is substantially flush, e.g., they are coplanar (e.g., homogeneous) to each other. Advantageously, such a flush arrangement may facilitate placing additional components (e.g., a fan, or a heat spreader, not shown) on the semiconductor package 200. Moreover, the flush arrangement may be beneficial to save on space in the semiconductor package 200.

Further, the semiconductor package 200 may include a underfill or a sealant 280 or a combination thereof. The underfill and/or sealant 280 may be disposed in the basket portion 224 and may embed the at least one semiconductor die 230 and the at least one wire 240, 240′. The underfill and/or sealant 280 may include epoxy polymer and silica particle composites. In an aspect, the underfill and/or sealant 280 may at least partially extend on a top surface 210a of the package substrate 210a or a top surface of the base die 250.

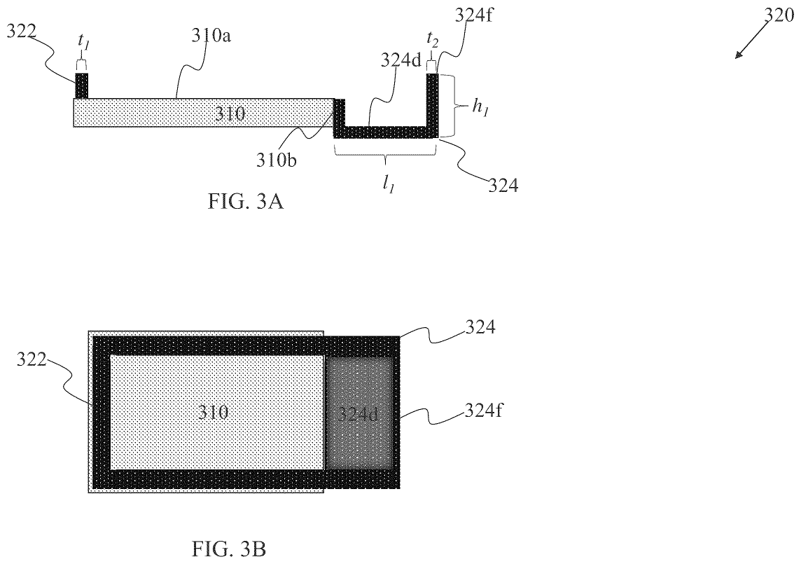

FIG. 3A is a cross-sectional view of a stiffener 320 on a package substrate 310, according to other aspects of the present disclosure. FIG. 3B is a top view of the stiffener 320 on the package substrate 310 of FIG. 3A.

Stiffener 320 may have a lateral portion 322 and a basket portion 324. As illustrated in FIG. 3A, the lateral portion 322 may refer to the portion of the stiffener 320 that is placed on the top surface 310a of the package substrate 310, rather than being laterally displaced from the top surface 310a of the package substrate 310. As illustrated in FIG. 3B, the lateral portion 322 may be disposed on the top surface 310a of the package substrate 310 and may surround, or partially surround, the base die (not shown). The lateral portion 322 may also surround, or partially surround, the electrical component (not shown). In this context, “lateral” is meant to indicate a side of the base die that is substantially perpendicular to the top surface of both the package substrate and the base die.

As illustrated in FIG. 3A, the basket portion 324 may refer to the portion of the stiffener 320 that is placed adjacent to a peripheral side surface 310b of the package substrate 310, rather than on the top surface 310a of the package substrate 310. The basket portion 324 may include a depressed portion 324d configured to house the at least one semiconductor die (not shown) and providing a surface for placement of the at least one semiconductor die. The basket portion 324 may further include a frame portion 324f, located at the peripheral end of the basket portion 324. The frame portion 324f may vertically extend to about the same height as the lateral portion 322. As illustrated in FIG. 3B, the basket portion 324 may extend from the top surface 310a of the package substrate 310.

In one aspect, the lateral portion 322 and the basket portion 324 of the stiffener 320 may be integrally formed from the same material. In one aspect, the stiffener 320 may be made of a material that may include a metal, e.g., an aluminum or stainless steel. Alternatively, the material of the stiffener 320 may include an organic material that is coated with a metal, e.g., an epoxy mold with a conductive aluminum layer or an aluminum-copper composite layer. In one aspect, the epoxy mold may be reinforced with fiber glass for improved rigidity. In one aspect, the stiffener 320 may include a metal coated inorganic layer, e.g., a silicon or a glass substrate with a conductive aluminum layer or an aluminum-copper composite layer. Accordingly, the stiffener 320 may be constructed of a metal material, a ceramic material, a polymer material, a composite material, or any combination thereof. Alternatively, the stiffener 320 may be constructed of a non-conductive base material that is electroplated with a metal. Advantageously, such a material may provide the additional function of a heat spreader. Accordingly, a further advantage of the semiconductor package 300 to the conventional semiconductor package 100 may be an improved heat transfer from the at least one semiconductor die.

A thickness t₁ of the lateral portion 322 may be about 0.5 mm to about 5 mm, or about 1.25 mm to about 2.50 mm. The thickness t₁ may vary depending on the size of the package substrate, the number of layers in the package substrate, the thickness of the package substrate core and the size of the base die. Depending on afore mentioned factors, the thickness t₁ may be varied to address warpage of the semiconductor package. The length l₁ of the basket portion 324 may be about 1 mm to about 30 mm, or about 5 mm to about 15 mm. The length l₁ may vary depending on the size and/or positioning of the at least one semiconductor die. The size of the at least one semiconductor die may vary depending on the number of transistors that could be packed within the same area. The height h₁ of the basket portion 324 may be about 200 μm to about 300 μm. The thickness t₂ of the basket portion 324 may be about 0.5 mm to about 5 mm, or about 1.25 mm to about 2.50 mm. The thickness t₂ may be substantially the same as the thickness t₁.

In one aspect, the stiffener 320 may be affixed to the package substrate 310 at selected or spot interface locations or continuously about an interface between the top surface 310a of the package substrate 310, the peripheral side surface 310b of the package substrate 310 and the stiffener 320 with an adhesive. Any suitable adhesive (e.g., epoxy cement, alumina or silicate-based ceramic adhesive, urethane adhesive, polyimide adhesive, etc.) may be utilized, such as an electrically conductive and/or an electrically non-conductive adhesive. For example, an electrically conductive and/or non-conductive adhesive may be used when the stiffener 320 is made of an electrically conductive material.

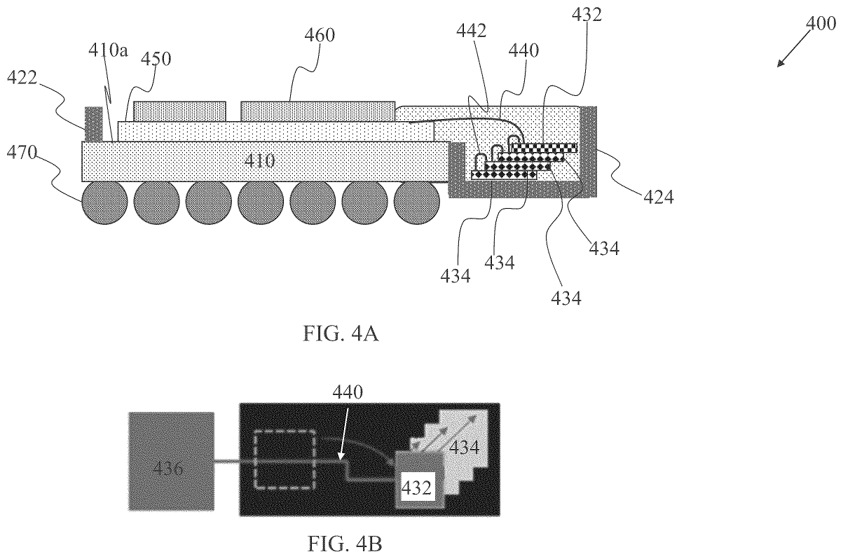

FIG. 4A is a cross-sectional view of a semiconductor package 400, according to other aspects of the present disclosure. FIG. 4B is a simplified topology view of the semiconductor package of FIG. 4A in accordance with an aspect of the disclosure.

In detail, FIG. 4A is a cross-sectional view of the semiconductor package 400. Referring to FIGS. 4A and 4B, the semiconductor package 400 includes most of the elements of the semiconductor packages 200 and 300 of FIGS. 2A, 2B, 2C, 2D, 3A, and 3B.

The semiconductor package 400 may include at least one stack of a master die 432 and a plurality of slave dies 434. Positioning-wise, as illustrated in FIG. 4A, the at least one stack of a master die 432 and plurality of slave dies 434 may be nested inside the basket portion 424, on the surface provided for by the depressed portion (not shown).

In the stack of master die 432 and slave dies 434, the master die 432 may be positioned on top of the plurality of slave dies 434. Each of the master die 432 and the slave dies 434 may be laterally displaced from each other, such that each of the master die 432 and the slave dies 434 appears to represent steps. In other words, each of the master die 432 and the slave dies 434 may be diagonally shifted from one another, such that each of the dies has one surface that faces the package substrate 410. In some aspects, the master die 432 may be disposed laterally shifted on a surface of an adjacent slave die 434, which in turn may be disposed laterally shifted on a surface of another adjacent slave die 434, and so on. While only one master die 432 and three slave dies 434 are shown in FIG. 4A, it is understood that any preferred number of each of the dies could be provided.

In some aspects, only the master die 432 may be required to connect to the package substrate 410 or the base die 450. To form a connection between the master die 432 and the slave dies 434, an inter-die wire 442 may be employed. For example, in some aspects, an inter-die wire 442 may connect the master die 432 with the slave die 434 that it is disposed on, and that slave die 434 may connect to the lower slave die 434 with another inter-die wire 442 until all of the slave dies 434 are connected (directly or indirectly) with the master die 432.

In some aspects, the at least one wire 440 and/or the inter-die wires 442 may couple the respective components by using reversed bonding. Unlike a normal wire bonding, reverse bonding may refer to a wire bonding type, in which the wire 440 or 442 may be ball-bonded to the master die 432 or the slave die 434 at one end, and then stitch-bonded to the base die 450 at the other end.

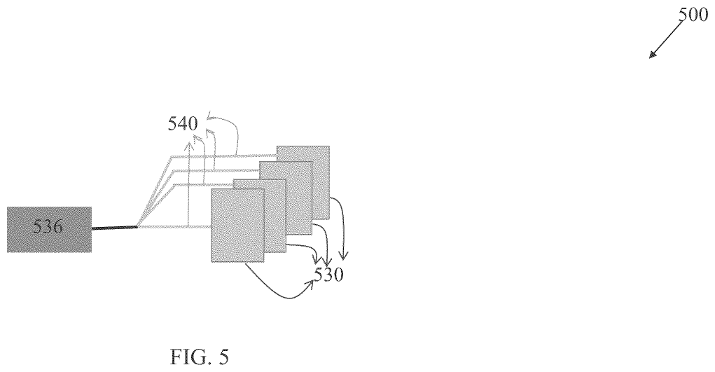

Advantageously, employing the inter-die wires 442 may simplify and improve the semiconductor die communication. For example, with reference to FIG. 4B, a controller 436 (e.g., a double data rate (DDR) controller, which may be included in the electrical component 460) may only have to communicate with the master die 432, regardless of the number of stacking of slave dies 434. Advantageously, such an arrangement may provide improved power delivery as compared with a wire arrangement as shown, e.g., in FIGS. 2A, 2B, 2C and 2D. E.g., as illustrated in FIG. 5, the simplified topology view 500 of the semiconductor package 200 is shown as including a controller 536 (e.g., a double data rate (DDR) controller, which may be included in the electrical component (not shown)) and a plurality of semiconductor dies 530, wherein each of the semiconductor dies 530 may be connected by a wire 540 to the controller 536, thereby involving a plurality of wires 540 that connect to the controller 536 instead of a single wire as shown in FIG. 4B.

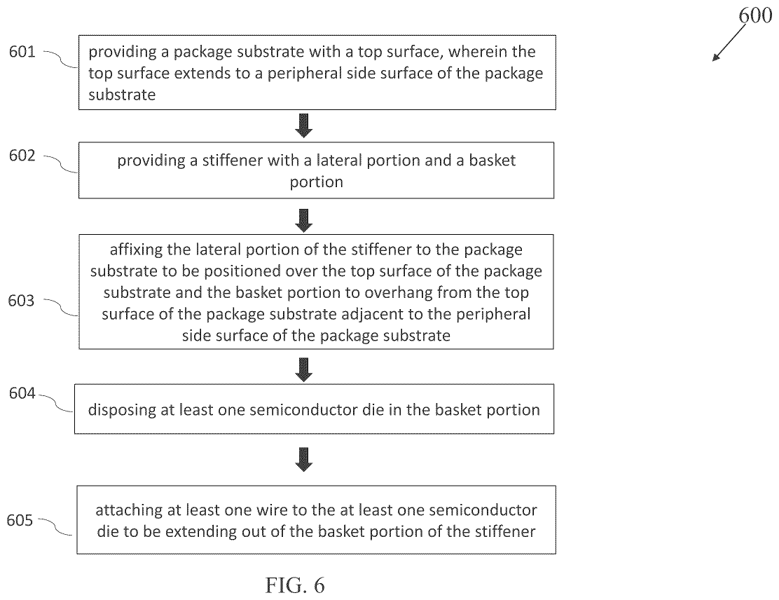

In another aspect there is provided a method 600. FIG. 6 shows a simplified flow diagram for an exemplary method for making a semiconductor package with a stiffener basket portion according to an aspect of the present disclosure.

The operation 601 may be directed to providing a package substrate with a top surface, in which the top surface extends to a peripheral side surface of the package substrate.

The operation 602 may be directed to providing a stiffener with a lateral portion and a basket portion.

The operation 603 may be directed to affixing the lateral portion of the stiffener to the package substrate to be positioned over the top surface of the package substrate and the basket portion to overhang from the top surface of the package substrate adjacent to the peripheral side surface of the package substrate.

The operation 604 may be directed to disposing at least one semiconductor die in the basket portion.

The operation 605 may be directed to attaching at least one wire to the at least one semiconductor die to be extending out of the basket portion of the stiffener.

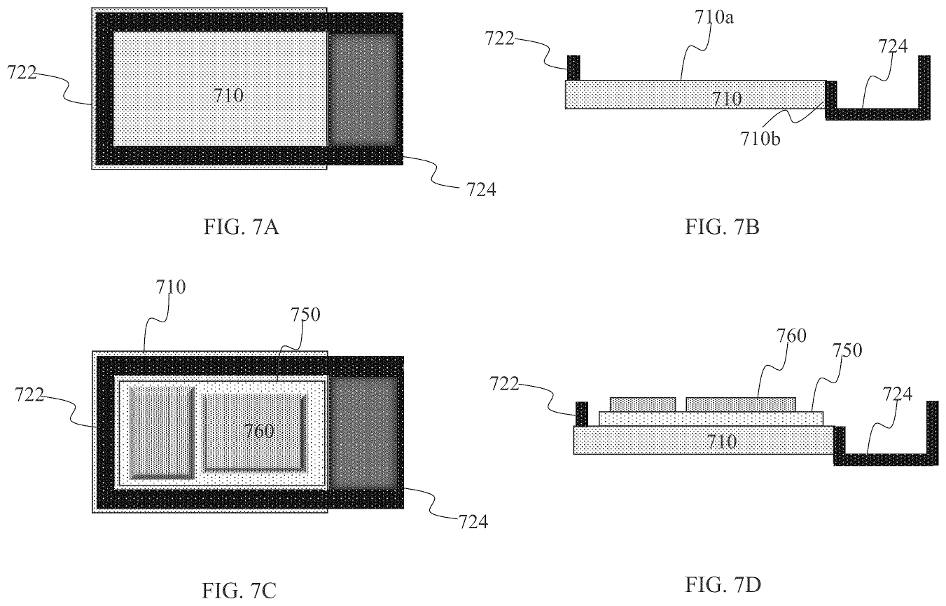

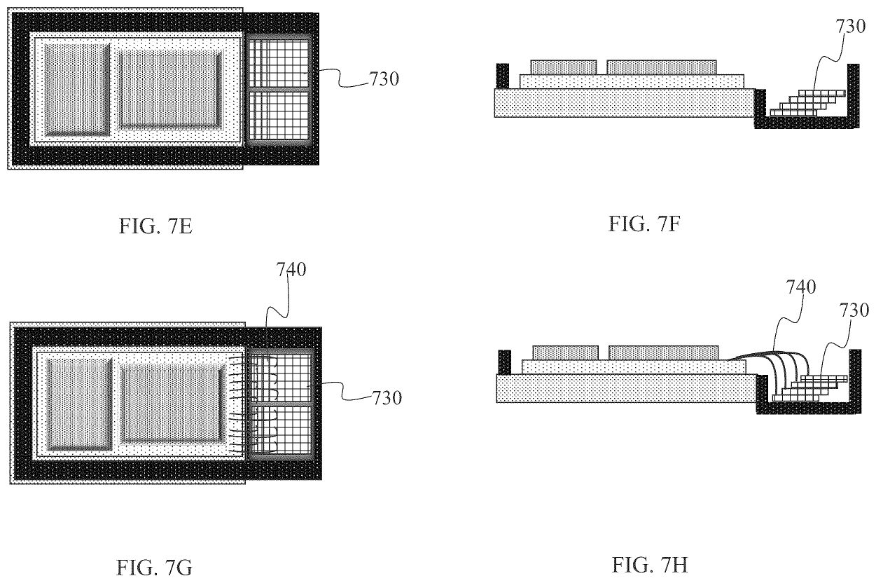

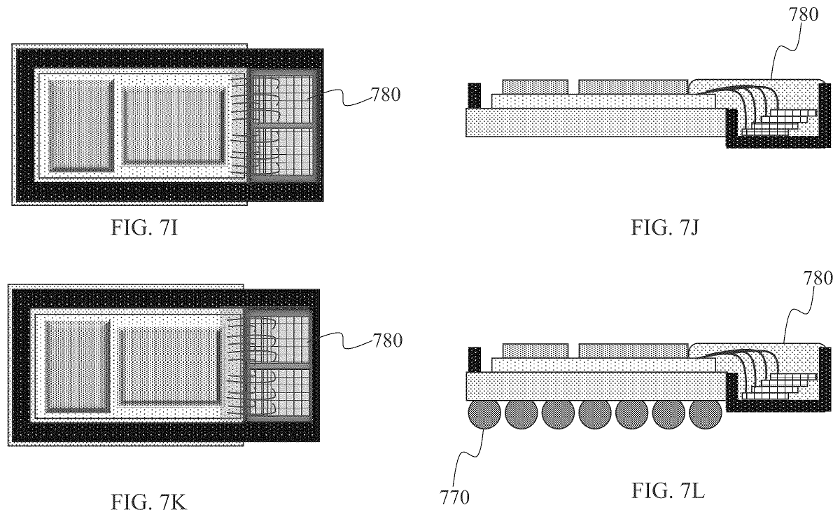

An exemplary method 700 is also illustrated in FIGS. 7A to 7L. In FIGS. 7A to 7L, FIG. 7B is a cross-sectional view of FIG. 7A, FIG. 7D is a cross-sectional view of FIG. 7C, FIG. 7F is a cross-sectional view of FIG. 7E, and so on. The method 700 may include: providing a package substrate 710 with a top surface 710a, in which the top surface 710a extends to a peripheral side surface 710b of the package substrate and attaching a stiffener to the package substrate 710, in which the stiffener includes a lateral portion 722 and a basket portion 724, in which the lateral portion 722 is positioned over the top surface 710a of the package substrate 710 and the basket portion 724 overhangs from the top surface 710a of the package substrate 710 adjacent to the peripheral side surface 710b of the package substrate (FIG. 7A and FIG. 7B). The method 700 may further include attaching a base die 750 on the top surface of the package substrate. The method 700 may further include attaching an electrical component 760 on the top surface of the base die 750 (FIG. 7C and FIG. 7D). The method 700 may further include applying an adhesive material on the basket portion and attaching at least one semiconductor die 730 to a surface of the basket portion (FIG. 7E and FIG. 7F). The method 700 may further include connecting the at least one semiconductor die 730 with the base die 750 by using at least one wire 740 (FIG. 7G and FIG. 7H). The method 700 may further include embedding the at least one semiconductor die 730 and the at least one wire 740 with an underfill and/or sealant 780 and curing the underfill and/or sealant 780 in an oven (FIG. 7I and FIG. 7J). The method 700 may further include attaching solder balls 770 to a bottom surface of the package substrate 710.

The fabrication methods and the choice of materials presented above are intended to be exemplary for forming the present semiconductor packages. It will be apparent to those ordinary skilled practitioners that the foregoing process operations may be modified without departing from the spirit of the present disclosure.

Further aspects of the disclosure and advantages described for the semiconductor package 200 of the previous aspect can be analogously valid for the methods 600 and 700, and vice versa. As the various features, material properties and advantages have already been described above and in the examples demonstrated herein, they shall not be iterated for brevity where possible.

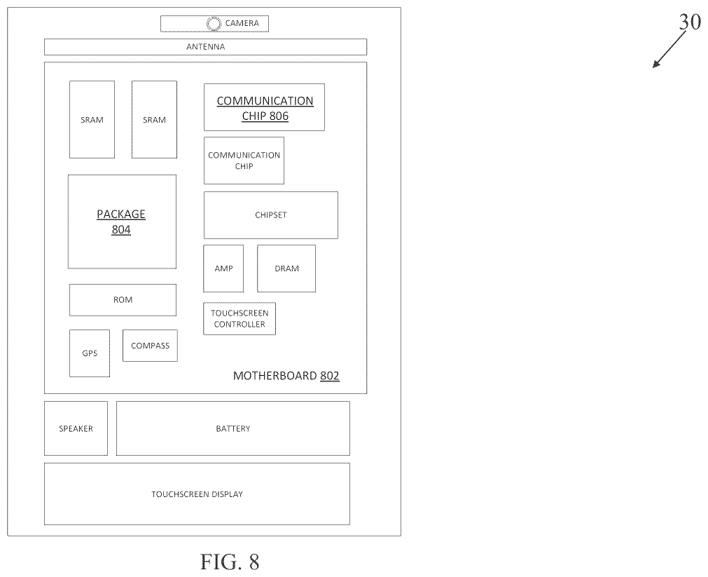

Aspects of the present disclosure may be implemented into a computing device using any suitable hardware and/or software. FIG. 8 schematically illustrates a computing device 30 that may include a semiconductor package as described herein, in accordance with some aspects. According to the present disclosure, the computing device 30 may include a printed circuit board, a semiconductor package, which has a package substrate with a stiffener basket portion.

In particular, the computing device may include a motherboard; and a semiconductor package coupled to the motherboard. The semiconductor package may include: a package substrate with a top surface, in which the top surface extends to a peripheral side surface of the package substrate; a stiffener with a lateral portion and a basket portion, in which the lateral portion is positioned over the top surface of the package substrate and the basket portion overhangs from the top surface of the package substrate adjacent to the peripheral side surface of the package substrate; at least one semiconductor die positioned in the basket portion of the stiffener; and at least one wire attached to the at least one semiconductor die and extending out of the basket portion of the stiffener.

In another aspect, the computing device 30 may house a board such as a motherboard 802. The motherboard 802 may include a number of components, including, but not limited to, a semiconductor package 804 and at least one communication chip 806. The semiconductor package 804 according to the present disclosure may be physically and electrically coupled to the motherboard 802. In some implementations, the at least one communication chip 806 may also be physically and electrically coupled to the motherboard 802. In further implementations, the communication chip 806 may be part of the semiconductor package 804.

Depending on its applications, computing device 30 may include other components that may or may not be physically and electrically coupled to the motherboard 802. These other components may include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, a Geiger counter, an accelerometer, a gyroscope, a speaker, a camera, and a mass storage device (such as hard disk drive, compact disk (CD), digital versatile disk (DVD), and so forth). In another aspect, the semiconductor package 804 of the computing device 30 may include a stiffener, as described herein.

The communication chip 806 may enable wireless communications for the transfer of data to and from the computing device 30. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some aspects they might not. The communication chip 806 may implement any of a number of wireless standards or protocols, including but not limited to Institute for Electrical and Electronics Engineers (IEEE) standards including Wi-Fi (IEEE 502.11 family), IEEE 502.16 standards (e.g., IEEE 502.16-2005 Amendment), Long-Term Evolution (LTE) project along with any amendments, updates, and/or revisions (e.g., advanced LTE project, ultra-mobile broadband (UMB) project (also referred to as “3GPP2”), etc.). IEEE 502.16 compatible BWA networks are generally referred to as WiMAX networks, an acronym that stands for Worldwide Interoperability for Microwave Access, which is a certification mark for products that pass conformity and interoperability tests for the IEEE 502.16 standards.

The communication chip 806 may also operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 806 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 806 may operate in accordance with Code Division Multiple Access (CDMA), Time Division Multiple Access (TDMA), Digital Enhanced Cordless Telecommunications (DECT), Evolution-Data Optimized (EV-DO), derivatives thereof, as well as any other wireless protocols that are designated as 3G, 4G, 5G, and beyond. The communication chip 806 may operate in accordance with other wireless protocols in other aspects.

The computing device 30 may include a plurality of communication chips 806. For instance, a first communication chip 806 may be dedicated to shorter range wireless communications such as Wi-Fi and Bluetooth and a second communication chip 806 may be dedicated to longer range wireless communications such as GPS, EDGE, GPRS, CDMA, WiMAX, LTE, Ev-DO, and others.

In various implementations, the computing device 30 may be a laptop, a netbook, a notebook, an ultrabook, a smartphone, a tablet, a personal digital assistant (PDA), an ultra mobile PC, a mobile phone, a desktop computer, a server, a printer, a scanner, a monitor, a set-top box, an entertainment control unit, a digital camera, a portable music player, or a digital video recorder. In an aspect, the computing device 30 may be a mobile computing device. In further implementations, the computing device 30 may be any other electronic device that processes data.

In a first example, there is a semiconductor package including a package substrate including: a package substrate with a top surface, in which the top surface extends to a peripheral side surface of the package substrate; a stiffener with a lateral portion and a basket portion, in which the lateral portion is positioned over the top surface of the package substrate and the basket portion overhangs from the top surface of the package substrate adjacent to the peripheral side surface of the package substrate; at least one semiconductor die positioned in the basket portion of the stiffener; and at least one wire attached to the at least one semiconductor die and extending out of the basket portion of the stiffener.

In a second example, the at least one semiconductor die of example 1 further includes at least one stack of a master die positioned on top of a plurality of slave dies.

In a third example, the master and slave dies of example 2 may be laterally offset from each other.

In a fourth example, the master die of example 2 or 3 may be connected to a beneath slave die via at least one inter-die wire, and each of the plurality of slave dies may be connected to a further beneath adjacent slave die via at least one further inter-die wire.

In a fifth example, the at least one semiconductor die of any of the preceding examples may be connected via the at least one wire to the top surface of the package substrate.

In a sixth example, the semiconductor package of any of the preceding examples may further include a base die disposed on the top surface of the package substrate, in which the at least one semiconductor die is connected via the at least one wire to the base die.

In a seventh example, the master die of example 6 may be connected via the at least one wire to the base die or the package substrate.

In an eighth example, the at least one wire of any of the preceding examples may be connected by reversed wire bonding to the package substrate.

In a ninth example, the at least one semiconductor die and the at least one wire of any of the preceding examples may be embedded by an underfill or a sealant.

In a tenth example, the semiconductor package of any of the preceding examples 6 to 8 may further include an electrical component positioned on a top surface of the base die, in which the at least one semiconductor die and the at least one wire are embedded by an underfill or a sealant; and in which a top surface of the underfill or the sealant is substantially at the same height with or at a lower height than a top surface of the electrical component.

In an eleventh example, the basket portion of the stiffener of any of the preceding examples may be configured to be a heat spreader for the at least one semiconductor die.

In a twelth example, the stiffener of any of the preceding examples may include a metal or an organic material that is coated with a metal.

In a thirteenth example, the semiconductor package of any of the preceding examples may include solder balls attached to a bottom surface of the package substrate and a section of the basket portion extending below the bottom surface of the package substrate; and in which the solder balls attached to the bottom surface have a diameter that is greater than a height of the section of the basket portion below the bottom surface of the package substrate.

In a fourteenth example, there is provided a method including: providing a package substrate with a top surface, in which the top surface extends to a peripheral side surface of the package substrate; providing a stiffener with a lateral portion and a basket portion; affixing the lateral portion of the stiffener to the package substrate to be positioned over the top surface of the package substrate and the basket portion to overhang from the top surface of the package substrate adjacent to the peripheral side surface of the package substrate; disposing at least one semiconductor die in the basket portion; and attaching at least one wire to the at least one semiconductor die to be extending out of the basket portion of the stiffener.

In a fifteenth example, the method of example 14 may further include applying an adhesive on the basket portion and adhesively affixing the at least one semiconductor die to the basket portion.

In a sixteenth example, the method of example 14 or 15 may further include disposing on the top surface of the package substrate a base die and attaching the at least one wire to the base die or the package substrate.

In a seventeenth example, the method of any of the examples 14 to 16 may further include applying an underfill or a sealant to embed the at least one semiconductor die and the at least one wire.

In an eighteenth example, there is provided a computing device including: a motherboard and a semiconductor package coupled to the motherboard, the semiconductor package including: a package substrate with a top surface, in which the top surface extends to a peripheral side surface of the package substrate; a stiffener with a lateral portion and a basket portion, in which the lateral portion is positioned over the top surface of the package substrate and the basket portion overhangs from the top surface of the package substrate adjacent to the peripheral side surface of the package substrate; at least one semiconductor die positioned in the basket portion of the stiffener; and at least one wire attached to the at least one semiconductor die and extending out of the basket portion of the stiffener.

In a nineteenth example, the at least one semiconductor die of example 18 may be connected via the at least one wire to the top surface of the package substrate.

In a twentieth example, the computing device of example 18 or 19 may further include a base die positioned on the top surface of the package substrate, in which the at least one semiconductor die is connected via the at least one wire to the base die.

The dimensions of the semiconductor package and the choice of materials presented above are intended to be exemplary for forming the semiconductor package. It will be apparent to those ordinary skilled practitioners that the foregoing process operations may be modified without departing from the spirit of the present disclosure.

The term “comprising” shall be understood to have a broad meaning similar to the term “including” and will be understood to imply the inclusion of a stated integer or operation or group of integers or operations but not the exclusion of any other integer or operation or group of integers or operations. This definition also applies to variations on the term “comprising” such as “comprise” and “comprises”.

By “about” or “approximately” in relation to a given numerical value, such as for thickness and height, it is meant to include numerical values within 10% of the specified value.

While the present disclosure has been particularly shown and described with reference to specific aspects, it should be understood by those skilled in the art that various changes in form and detail may be made therein without departing from the spirit and scope of the present disclosure as defined by the appended claims. The scope of the present disclosure is thus indicated by the appended claims and all changes which come within the meaning and range of equivalency of the claims are therefore intended to be embraced.

What is claimed is:

1. A semiconductor package comprising:
a package substrate with a top surface, wherein the top surface extends to a peripheral side surface of the package substrate;
a stiffener with a lateral portion and a basket portion, wherein the lateral portion is positioned over the top surface of the package substrate and the basket portion overhangs from the top surface of the package substrate adjacent to the peripheral side surface of the package substrate;
at least one semiconductor die positioned in the basket portion of the stiffener; and
at least one wire attached to the at least one semiconductor die and extending out of the basket portion of the stiffener.

2. The semiconductor package of claim 1, wherein the at least one semiconductor die further comprises at least one stack of a master die positioned on top of a plurality of slave dies.

3. The semiconductor package of claim 2, wherein the master and slave dies are laterally offset from each other.

4. The semiconductor package of claim 2, wherein the master die is connected to a beneath slave die via at least one inter-die wire, and each of the plurality of slave dies is connected to a further beneath adjacent slave die via at least one further inter-die wire.

5. The semiconductor package of claim 1, wherein the at least one semiconductor die is connected via the at least one wire to the top surface of the package substrate.

6. The semiconductor package of claim 1, further comprising a base die disposed on the top surface of the package substrate, wherein the at least one semiconductor die is connected via the at least one wire to the base die.

7. The semiconductor package of claim 6, wherein the master die is connected via the at least one wire to the base die or the package substrate.

8. The semiconductor package of claim 1, wherein the at least one wire is connected by reversed wire bonding to the package substrate.

9. The semiconductor package of claim 1, wherein the at least one semiconductor die and the at least one wire are embedded by an underfill or a sealant.

10. The semiconductor package of claim 6, further comprising an electrical component positioned on a top surface of the base die, wherein the at least one semiconductor die and the at least one wire are embedded by an underfill or a sealant; and
wherein a top surface of the underfill or the sealant is substantially at the same height with or at a lower height than a top surface of the electrical component.

11. The semiconductor package of claim 1, wherein the basket portion of the stiffener is configured to be a heat spreader for the at least one semiconductor die.

12. The semiconductor package of claim 1, wherein the stiffener comprises a metal or an organic material that is coated with a metal.

13. The semiconductor package of claim 1, further comprising solder balls attached to a bottom surface of the package substrate and a section of the basket portion extending below the bottom surface of the package substrate; and wherein the solder balls attached to the bottom surface have a diameter that is greater than a height of the section of the basket portion below the bottom surface of the package substrate.

14. A method comprising:
providing a package substrate with a top surface, wherein the top surface extends to a peripheral side surface of the package substrate;
providing a stiffener with a lateral portion and a basket portion;
affixing the lateral portion of the stiffener to the package substrate to be positioned over the top surface of the package substrate and the basket portion to overhang from the top surface of the package substrate adjacent to the peripheral side surface of the package substrate;
disposing at least one semiconductor die in the basket portion; and
attaching at least one wire to the at least one semiconductor die to be extending out of the basket portion of the stiffener.

15. The method of claim 14, further comprising applying an adhesive on the basket portion and adhesively affixing the at least one semiconductor die to the basket portion.

16. The method of claim 14, further comprising disposing on the top surface of the package substrate a base die and attaching the at least one wire to the base die or the package substrate.

17. The method of claim 14, further comprising applying an underfill or a sealant to embed the at least one semiconductor die and the at least one wire.

18. A computing device comprising:
a motherboard and a semiconductor package coupled to the motherboard, the semiconductor package comprising:
a package substrate with a top surface, wherein the top surface extends to a peripheral side surface of the package substrate;
a stiffener with a lateral portion and a basket portion, wherein the lateral portion is positioned over the top surface of the package substrate and the basket portion overhangs from the top surface of the package substrate adjacent to the peripheral side surface of the package substrate;
at least one semiconductor die positioned in the basket portion of the stiffener; and
at least one wire attached to the at least one semiconductor die and extending out of the basket portion of the stiffener.

19. The computing device of claim 18, wherein the at least one semiconductor die is connected via the at least one wire to the top surface of the package substrate.

20. The computing device of claim 18, further comprising a base die positioned on the top surface of the package substrate, wherein the at least one semiconductor die is connected via the at least one wire to the base die.
